(19) United States
(12) Patent Application Publication
(10) Pub. No.: US 2024/0290729 A1
(43) Pub. Date: Aug. 29, 2024

(54) SEMICONDUCTOR PACKAGES INCLUDING SHIELDING STRUCTURES

(71) Applicant: Infineon Techologies AG, Neubiberg (DE)

(72) Inventors: Tuncay ERDOEL, Unterhaching (DE); Walter HARTNER, Bad Abbach (DE); Pietro BRENNER, Ebersberg (DE); Simon KORNPROBST, Stephanskirchen (DE); Guido WEISS, Pielenhofen (DE)

(21) Appl. No.: 18/435,499

(22) Filed: Feb. 7, 2024

(30) Foreign Application Priority Data
Feb. 24, 2023 (DE) 102023201690.7

(51) Int. Cl. H01L 23/552; H01L 23/00; H01L 23/31; H01L 23/498

(52) U.S. Cl. CPC H01L 23/552; H01L 23/3157; H01L 23/49816; H01L 24/16; H01L 2224/16225

(57) ABSTRACT

A semiconductor package includes a semiconductor chip including multiple radio frequency channels. The semiconductor package further includes a signal port arranged external to the semiconductor chip and associated with one of the multiple radio frequency channels. The semiconductor package further includes a shielding structure at least partially surrounding the signal port when viewed in a first direction, wherein the shielding structure is configured to reduce a propagation of an interference signal from and/or to the signal port in a second direction perpendicular to the first direction.

### CROSS-REFERENCE TO RELATED APPLICATION

This application claims priority to German Patent Application No. 102023201690.7 filed on Feb. 24, 2023, the content of which is incorporated by reference herein in its entirety.

### TECHNICAL FIELD

The present disclosure relates to semiconductor packages including shielding structures. In addition, the present disclosure relates to methods for manufacturing such semiconductor packages.

### BACKGROUND

In radio frequency applications, such as e.g., radar systems, more and more functions are packed into components with small packages which may result in signal interferences and degradation of signal-to-signal isolation between radar signal channels. Manufacturers of radio frequency devices are constantly striving to improve their products. In particular, it may be desirable to provide radio frequency devices having improved isolation properties between the individual radar signal channels. In this connection, it may also be desirable to provide suitable methods for manufacturing such devices.

### SUMMARY

An aspect of the present disclosure relates to a semiconductor package. The semiconductor package includes a semiconductor chip including multiple radio frequency channels. The semiconductor package further includes a signal port arranged external to the semiconductor chip and associated with one of the multiple radio frequency channels. The semiconductor package further includes a shielding structure at least partially surrounding the signal port when viewed in a first direction, wherein the shielding structure is configured to reduce a propagation of an interference signal from and/or to the signal port in a second direction perpendicular to the first direction.

An aspect of the present disclosure relates to a method for manufacturing a semiconductor package. The method includes arranging a signal port external to a semiconductor chip, wherein the signal port is associated with one of multiple radio frequency channels of the semiconductor chip. The method further includes manufacturing a shielding structure at least partially surrounding the signal port when viewed in a first direction, wherein the shielding structure is configured to reduce a propagation of an interference signal from and/or to the signal port in a second direction perpendicular to the first direction.

### BRIEF DESCRIPTION OF THE DRAWINGS

The accompanying drawings are included herein to provide a further understanding of aspects of the present disclosure. The drawings illustrate aspects and together with the description serve to explain principles of aspects. Other aspects and many of the intended advantages of aspects will be readily appreciated as they become better understood by reference to the following detailed description. The elements of the drawings are not necessarily to scale relative to each other. Like reference signs may designate corresponding similar parts.

FIGS. 1A and 1B schematically illustrate a top view and a cross-sectional side view of a semiconductor package 100 in accordance with the disclosure.

FIG. 2 schematically illustrates a top view of a solder ball placement on a bottom side of a semiconductor package in accordance with the disclosure.

FIG. 3 schematically illustrates a cross-sectional side view of a semiconductor package 300 in accordance with the disclosure.

FIG. 4 schematically illustrates a cross-sectional side view of a semiconductor package 400 in accordance with the disclosure.

FIG. 5 schematically illustrates a cross-sectional side view of a semiconductor package 500 in accordance with the disclosure.

FIG. 6 schematically illustrates a cross-sectional side view of a semiconductor package 600 in accordance with the disclosure.

FIG. 7 schematically illustrates a cross-sectional side view of a semiconductor package 700 in accordance with the disclosure.

FIG. 8 schematically illustrates a cross-sectional side view of a semiconductor package 800 in accordance with the disclosure.

FIG. 9 schematically illustrates a cross-sectional side view of a semiconductor package 900 in accordance with the disclosure.

FIG. 10 schematically illustrates top views of two semiconductor packages 1000A and 1000B.

FIG. 11 schematically illustrates top views of two semiconductor packages 1100A and 1100B.

FIG. 12 schematically illustrates a cross-sectional side view and a top view of a semiconductor package 1200 in accordance with the disclosure.

FIGS. 13A and 13B schematically illustrate a top view and a cross-sectional side view of a semiconductor package 1300 in accordance with the disclosure.

FIGS. 14A and 14B schematically illustrate a top view and a cross-sectional side view of a semiconductor package 1400 in accordance with the disclosure.

FIGS. 15A and 15B illustrate isolation properties of various semiconductor packages.

FIG. 16 illustrates a flowchart of a method for manufacturing a semiconductor package in accordance with the disclosure.

FIGS. 17A to 17J schematically illustrate a method for manufacturing a semiconductor package in accordance with the disclosure.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

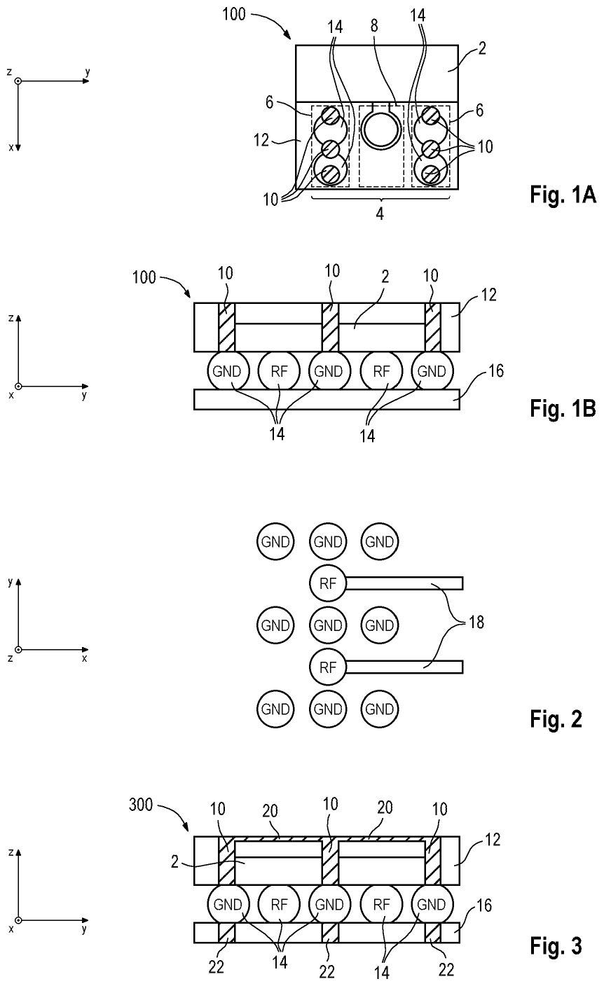

The semiconductor package 100 of FIGS. 1A and 1B may include a semiconductor chip (or semiconductor die) 2 including multiple radio frequency channels. One or more signal ports 4 may be arranged external to the semiconductor chip 2, wherein each of the signal ports 4 may be associated with one of the multiple radio frequency channels. For the sake of simplicity, only one signal port 4 is illustrated in the top view of FIG. 1A. The signal port 4 may include a ground line portion 6 and a signal line portion 8, wherein the ground line portion 6 may at least partially surround the signal line portion 8. The signal port 4 may be configured to transfer radio frequency signals between the semiconductor chip 2 and one or multiple external components, such as e.g., an antenna or an external semiconductor chip.

The semiconductor package 100 may include a shielding structure 10 at least partially surrounding the signal port 4 when viewed in a first direction. The first direction may be substantially perpendicular to a main surface of the semiconductor chip 2. In the illustrated example, the first direction may correspond to the z-direction. The shielding structure 10 may be configured to reduce a propagation of an interference signal from and/or to the signal port 4 in a second direction perpendicular to the first direction. In the illustrated example, the second direction may extend in the x-y-plane.

The semiconductor package 100 may include an encapsulation material 12 at least partially encapsulating the semiconductor chip 2. In addition, the shielding structure 10 may be at least partially arranged in the encapsulation material 12. The shielding structure 10 may be configured to reduce a propagation of interference signals through the encapsulation material 12 in the x-y-plane. The semiconductor package 100 may further include multiple external connection elements 14 configured to mechanically and electrically connect or couple the semiconductor package 100 to a printed circuit board 16. The printed circuit board 16 may be seen as a part of the illustrated device or not.

The semiconductor chip 2 (or electronic circuits thereof) may operate in a frequency range of greater than about 1 GHz, in some examples greater than about 10 GHz. The semiconductor chip 2 may thus also be referred to as radio frequency chip or high frequency chip or microwave frequency chip. More particular, the semiconductor chip 2 may operate in a radio frequency range or microwave frequency range, which may range from about 1 GHz to about 1 THz, more particular from about 10 GHz to about 300 GHz. Microwave circuits may include, for example, microwave transmitters, microwave receivers, microwave transceivers, microwave sensors, microwave detectors, etc. Devices in accordance with the disclosure may be used for radar applications in which the frequency of the radio frequency signals may be modulated. Accordingly, the semiconductor chip 2 may particularly correspond to a radar chip.

Radar microwave devices may e.g., be used in automotive, industrial, military and/or defense applications for range and speed measuring systems. For example, automotive applications may include advanced driver assistant systems, automatic vehicle cruise control systems, vehicle anti-collision systems, etc. Such systems may operate in the microwave frequency range, for example in the 24 GHZ, 76 GHz, or 79 GHz frequency bands. A use of radar microwave systems may provide constant and efficient driving of vehicles. An efficient driving style may, for example, reduce fuel consumption such that CO₂ emission may be reduced and energy savings may be enabled. In addition, abrasion of vehicle tires, brake discs and brake pads may be reduced, thereby reducing fine dust pollution. Improved radar systems, as specified herein, may thus contribute to green technology solutions, e.g., climate-friendly solutions providing an improved mitigation of energy use.

The devices described herein need not be limited to the example technical areas mentioned above. In further examples, the concepts presented herein may also be implemented for the following RF applications (list not exhaustive): technologies at frequencies beyond 100 GHz, e.g., THz technologies; 5G; 6G; radar-signal based face and gesture recognition sensors; high data transfer communication systems and wireless backhaul systems; body scanning systems for security; medical and health monitoring systems (e.g., medical sensors and data transfer); GBit Automotive Ethernet.

In radio frequency applications, such as e.g., radar systems, more and more functions may be packed into components with small packages which may result in signal interferences and degradation of signal-to-signal isolation between the radar frequency channels. During an operation of the semiconductor package 100 interference and crosstalk may occur between adjacent signal ports 4 associated with different radio frequency channels. The shielding structure 10 may be configured to reduce a propagation of interference signals through the encapsulation material 12 between neighboring signal ports 4. That is, the shielding structure 10 may be configured to provide an electrical shielding between neighboring signal ports 4, thereby improving an isolation performance of the semiconductor package 100.

The shielding structure 10 may include or may be made of an electrically conductive material, such as e.g., a metal and/or a metal alloy. For example, the shielding structure 10 may be formed by one or multiple three-dimensional metal components. In this regard, the term “three-dimensional” may refer to components having dimensions in each spatial direction of more than about 25 μm, or more than about 50 μm, or more than about 75 μm, or more than about 100 μm. Such three-dimensional metal components may thus be distinguished from, for example, ground metallizations included in an electrical redistribution layer and having a dimension smaller than the above given values in at least one spatial direction.

Metal components of the shielding structure 10 may include at least one of a metal via, a metal strip, a metal bar, a metal wall, or a metal mesh. In the side view of FIG. 1B, the components of the shielding structure 10 may exemplarily correspond to metal via bars extending in the vertical z-direction and having a substantially rectangular shape. In other examples, however, components of the shielding structure 10 may be tilted and/or may have a rounded, curved, spherical, or elliptical shape.

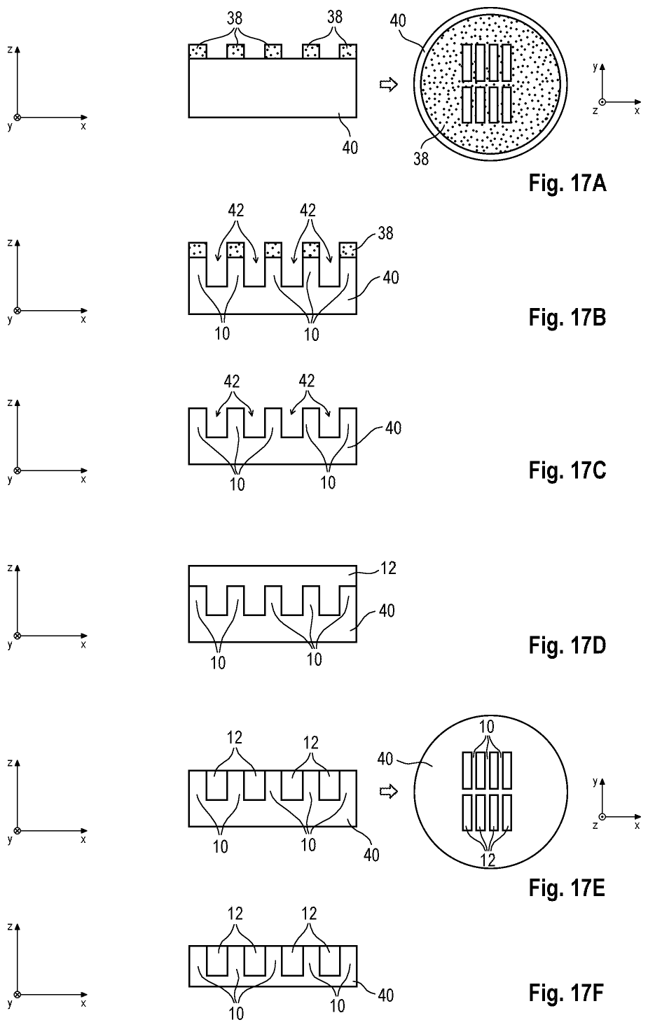

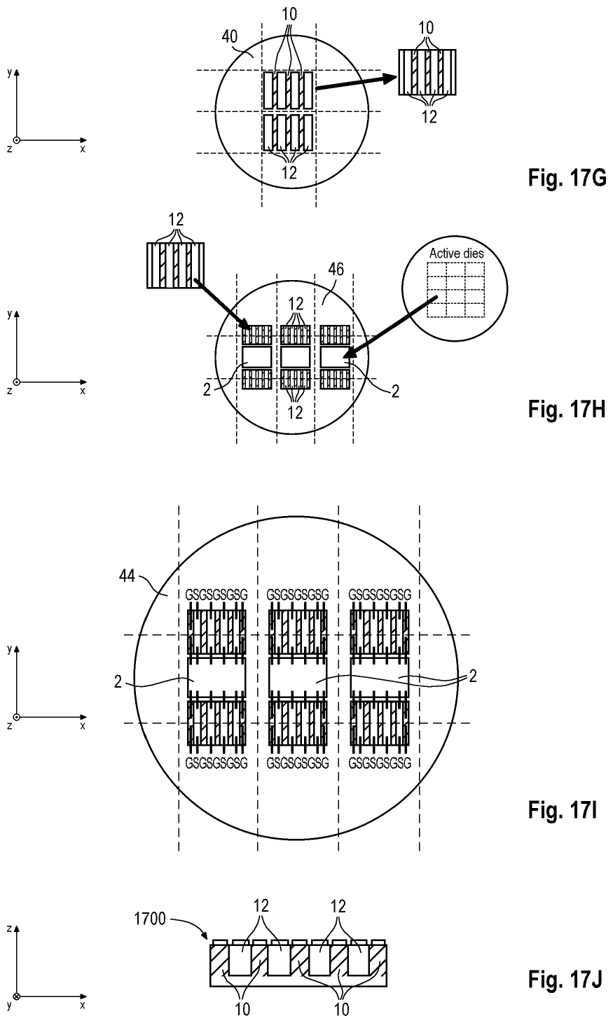

In further examples, the shielding structure 10 or parts thereof may not necessarily be electrically conductive. For example, the shielding structure 10 may include or may be made of a semiconductor material, such as e.g., silicon. In this case, the semiconductor material may be doped to such an extent that the shielding structure 10 may be configured to absorb radiation having a frequency in one of the operating frequency ranges described above. In one specific example, the shielding structure 10 may include a semiconductor material including multiple trenches filled with an encapsulation material, such as e.g., a mold compound. Shielding structures including a semiconductor material and associated manufacturing methods are discussed in connection with FIGS. 14 and 17.

The semiconductor package 100 may include an electrical redistribution layer including one or multiple signal lines (or signal line portions). For example, the signal line portion 8 may be part of an electrical redistribution layer. The signal line portion 8 may provide an electrical connection between the signal port 4 and internal electronic structures of the semiconductor chip 2. When viewed in the z-direction, the shielding structure 10 may at least partially surround the signal line portion 8, thereby reducing a propagation of interference signals from and/or to the signal line portion 8 and providing an electrical shielding between neighboring signal ports 4. In this regard, the shielding structure 10 may also be referred to as a shielding fence or a shielding cage.

The shielding structure 10 may be electrically connected to a non-floating electrical potential. The non-floating electrical potential may correspond to a ground potential. In one specific example, the shielding structure 10 may be electrically connected to a ground metallization of an electrical redistribution layer.

In one example, the shielding structure 10 may exclusively surround the signal port 4. Alternatively, the shielding structure 10 may exclusively surround the signal port 4 and the signal line. That is, the shielding structure 10 may be configured for an exclusive shielding of the signal port 4 and/or the signal line, but may not necessarily be configured for a shielding of additional package components. A shielding structure in accordance with the disclosure may thus be distinguished from, for example, shielding structures surrounding the entire semiconductor package.

The external connection elements 14 may include one or multiple ground connection elements (see “GND”) that may be electrically connected to and/or may be part of the ground line portions 8. In addition, the external connection elements 14 may include one or multiple signal or radio frequency connection elements (see “RF”) that may be electrically connected to and/or may be part of the signal line portions 8. In the illustrated case, the external connection elements 14 may exemplarily correspond to solder balls.

When viewed in the z-direction, the ground connection elements GND may at least partially overlap the components of the shielding structure 10. For example, the external connection elements 14 overlapping the components of the shielding structure 10 may be ground solder balls. In the illustrated example, the components of the shielding structure 10 may be arranged directly over the ground connection elements GND. In further examples, the components of the shielding structure 10 may also be displaced or shifted in the x-y-plane as long as they still suitable surround the signal port 4.

The encapsulation material 12 may include or may be made of at least one of the following materials: mold compound, epoxy, filled epoxy, glass fiber filled epoxy, imide, thermoplast, thermoset polymer, polymer blend, etc. In the illustrated example, the encapsulation material 12 may cover the top surface and the side surfaces of the semiconductor chip 2, while the bottom surface of the semiconductor chip 2 may be uncovered by the encapsulation material 12. The bottom surfaces of the encapsulation material 12 and the semiconductor chip 2 may be substantially arranged in a common plane.

The encapsulation material 12 may form a housing (or a package) of the semiconductor chip 2. In general, the semiconductor package 100 may be based on any suitable package technology, such as e.g., Flip-Chip BGAs (Ball Grid Arrays), Wirebond-BGAs, eWLB (embedded Wafer Level Ball Grid Arrays), FOWLP (Fan Out Wafer Level Packaging), etc. In the illustrated case, the semiconductor package 100 may exemplarily correspond to a wafer level package, which may be manufactured based on an eWLB (embedded Wafer Level Ball Grid Array) technique. Here, the signal port 4 and the shielding structure 10 may be laterally displaced to the semiconductor chip 2 when viewed in the z-direction. In other words, the signal port 4 and the shielding structure 10 may be arranged in a fan-out area of the semiconductor package.

FIG. 2 schematically illustrates a top view of a solder ball placement on a bottom side of a semiconductor package in accordance with the disclosure. For example, the solder ball placement of FIG. 2 may be used for the semiconductor package 100 of FIG. 1. The illustrated example shows an example number of two radio frequency solder balls RF. Each of the radio frequency solder balls RF may be surrounded by an example number of three ground solder balls GND on each side. It is to be noted that the two radio frequency solder balls RF may share the three ground solder balls GND arranged in between. It is further to be noted that a radio frequency solder ball can be shifted in x-direction to the right or to the left. For example, cach of the radio frequency solder balls RF may be electrically connected to a radio frequency line 18 of a printed circuit board.

The semiconductor package 300 of FIG. 3 may include some or all features of the semiconductor package 100 of FIG. 1. The semiconductor package 300 may optionally include one or multiple metal layers (or metal patches) 20 arranged over the shielding structure 10. The metal layer 20 may extend in the second direction, e.g., in the x-y-plane. The metal layer 20 may electrically connect multiple metal components of the shielding structure 10. In the illustrated example, the metal layer 20 may electrically connect top portions of the metal components while bottom portions of the metal components may c.g., be electrically connected to a ground metallization of an electrical redistribution layer. The ground solder balls GND may be connected to via connections 22 arranged in the printed circuit board 16.

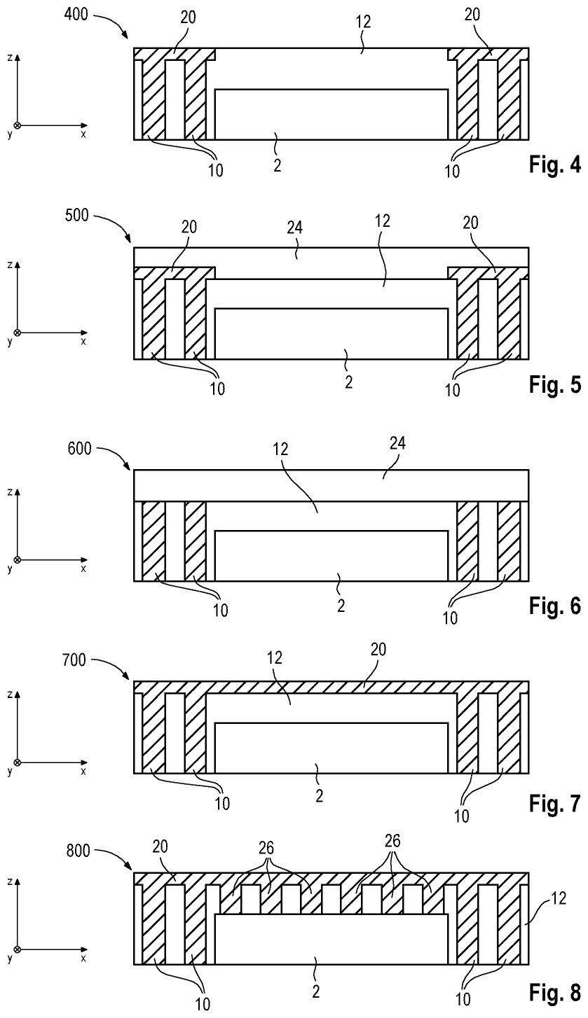

The semiconductor package 400 of FIG. 4 may include some or all features of previously discussed semiconductor packages in accordance with the disclosure. In particular, the semiconductor package 400 may be at least partially similar to the semiconductor package 300 of FIG. 3. The semiconductor package 400 may include metal layers 20 arranged over the shielding structure 10 and extending in the x-y-plane. The metal layers 20 may electrically connect multiple metal components of the shielding structure 10. In the chosen perspective of FIG. 4, it can be seen that the shielding structure 10 may be laterally displaced to the semiconductor chip 2. For the sake of simplicity, but in no way limiting, external connection elements of the semiconductor package 400 are not shown.

The semiconductor package 500 of FIG. 5 may include some or all features of previously discussed semiconductor packages in accordance with the disclosure. In particular, the semiconductor package 500 may be at least partially similar to the semiconductor package 400 of FIG. 4. The semiconductor package 500 may include an absorber material 24 that may be arranged over the shielding structure 10. The absorber material 24 may be configured to absorb interference signals generated by at least one of the multiple radio frequency channels of the semiconductor chip 2. In this regard, the absorber material 24 may be configured to reduce reflection of radiation from areas of the top surface of the semiconductor package 500 that are uncovered by the metal layers 20. The absorber material 24 may include a radio frequency absorber material. For example, the absorber material 24 may include or may be made of at least one of carbon, rubber material, conducting polymer, chiral material, or a polymer matrix including at least one of conducting particles or magnetic particles.

The semiconductor package 600 of FIG. 6 may include some or all features of previously discussed semiconductor packages in accordance with the disclosure. In particular, the semiconductor package 600 may be at least partially similar to the semiconductor package 500 of FIG. 5. In contrast to FIG. 5, the semiconductor package 600 may not necessarily include a metal layer electrically connecting components of the shielding structure 10. In the illustrated example, the absorber material 24 may entirely cover the top surface of the encapsulation material 12. More general, the absorber material 24 may cover at least about 80%, or at least about 85%, or at least about 90%, or at least about 95% of the top surface of the encapsulation material 12.

The semiconductor package 700 of FIG. 7 may include some or all features of previously discussed semiconductor packages in accordance with the disclosure. In particular, the semiconductor package 700 may be at least partially similar to the semiconductor package 400 of FIG. 4. In the illustrated example, the metal layer 20 may entirely cover the top surface of the encapsulation material 12. More general, the metal layer 20 may cover at least about 80%, or at least about 85%, or at least about 90%, or at least about 95% of the top surface of the encapsulation material 12.

The semiconductor package 800 of FIG. 8 may include some or all features of previously discussed semiconductor packages in accordance with the disclosure. In particular, the semiconductor package 800 may be at least partially similar to the semiconductor package 700 of FIG. 7. The semiconductor package 800 may include one or multiple electrically conductive elements 26 that may be arranged in the encapsulation material 12 and over the top surface of the semiconductor chip 2. The electrically conductive elements 26 may be configured to reduce a propagation of interference signals through the encapsulation material 12 in the second direction, e.g., in the x-y-plane. Referring back to FIG. 7, coverage of the package top side by the metal layer 20 to a large extent may result in guidance of electromagnetic waves through the package in a lateral direction, e.g., in the x-y-plane. The electrically conductive elements 26 may be configured to block such lateral electromagnetic wave guidance, thereby improving isolation between neighboring radio frequency channels.

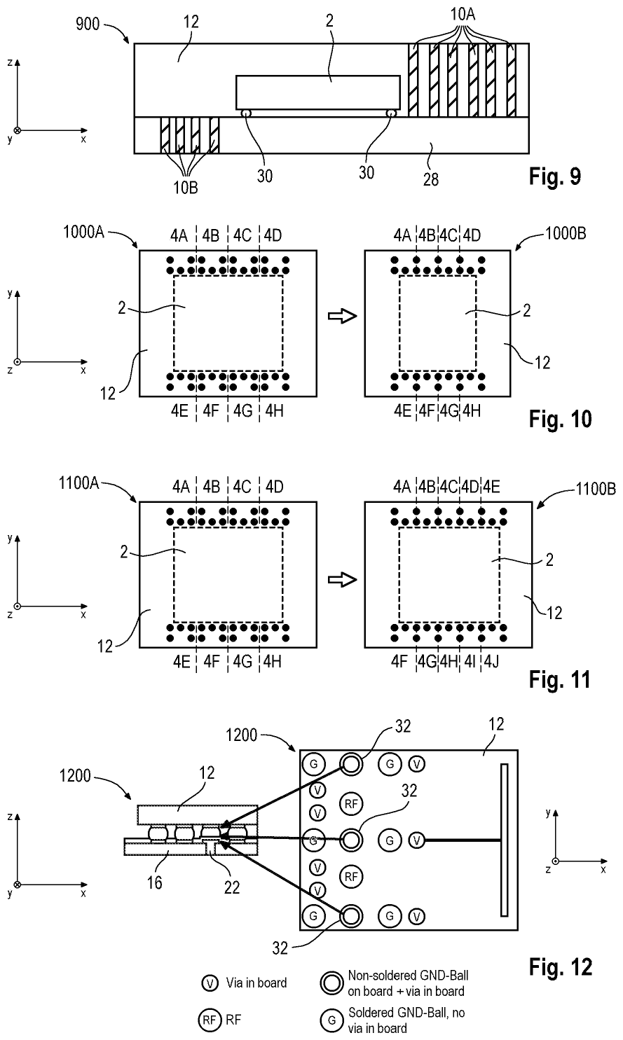

The semiconductor package 900 of FIG. 9 may include some or all features of previously discussed semiconductor packages in accordance with the disclosure. Compared to foregoing examples, the semiconductor package 900 may correspond to a different package type. In particular, the semiconductor package 900 may be a FCBGA (Flip Chip Ball Grid Array) semiconductor package including a ball grid array substrate 28. The ball grid array substrate 28 may also be referred to as laminate layer, interposer, or redistribution interposer.

The semiconductor chip 2 may be mounted on top of the ball grid array substrate 28 based on a flip chip technique. In this regard, the semiconductor chip 2 may be electrically and mechanically connected to the ball grid array substrate 28 by one or multiple solder depots 30. Electronic signal routing structures arranged in the ball grid array substrate 28 may be configured to electrically redistribute electric signals between the semiconductor chip 2 and external connection elements (not illustrated) that may be arranged on the bottom surface of the ball grid array substrate 28.

Similar to previously described examples, the semiconductor package 900 may include a first shielding structure 10A arranged in the encapsulation material 12. In addition, the semiconductor package 900 may include a second shielding structure 10B arranged in the ball grid array substrate 28. The second shielding structure 10B may include some or all features of shielding structures discussed in connection with foregoing examples. In particular, the second shielding structure 10B may be configured to reduce a propagation of interference signals through the ball grid array substrate 28 in a direction extending in the x-y-plane.

FIG. 10 schematically illustrates top views of two semiconductor packages 1000A and 1000B. Each of the semiconductor packages 1000A and 1000B may include multiple signal ports associated with radio frequency channels that may e.g., include TX channels and/or RX channels. In the illustrated example, each of the semiconductor packages 1000A and 1000B may include four signal ports 4A to 4D arranged at the top and four signal ports 4E to 4H arranged at the bottom. Each signal port may include a signal line portion surrounded by two ground line portions as e.g., described in connection with FIG. 1A.

In the semiconductor package 1000A, two ground line portions may be arranged between adjacent signal line portions. In contrast to this, in the semiconductor package 1000B, cach signal port may share a same ground line portion with an adjacent signal port, wherein the ground line portion may be arranged between the signal line portion of the signal port and the signal line portion of the adjacent signal port. Due to the shared ground line portions, the semiconductor package 1000B may accommodate an equal number of signal ports on a smaller area compared to the semiconductor package 1000A. In particular, dimensions of the semiconductor package 1000B may be reduced in the x-direction.

FIG. 11 schematically illustrates top views of two semiconductor packages 1100A and 1100B which may be similar to the semiconductor packages 1000A and 1000B of FIG. 10. The semiconductor packages 1100A and 1100B may have similar dimensions. However, due to ground line portions shared between adjacent signal ports, the semiconductor package 1100B may provide a higher number of signal ports compared to the semiconductor package 1100A. In particular, the semiconductor package 1100B may include five signal ports 4A to 4E arranged at the top and five signal ports 4F to 4J arranged at the bottom, c.g., a total number of ten signal ports. In contrast to this, the semiconductor package 1100A may include four signal ports 4A to 4D arranged at the top and four signal ports 4E to 4H arranged at the bottom, e.g., a total number of only eight signal ports.

FIG. 12 schematically illustrates a cross-sectional side view and a top view of a semiconductor package 1200 in accordance with the disclosure. The semiconductor package 1200 may include some or all features of previously discussed semiconductor packages in accordance with the disclosure. The top view on the right shows positions of via connections 22 (see “V”) arranged in the printed circuit board 16, positions of radio frequency solder balls (scc “RF”), positions of ground solder balls (see “G”) that may be soldered to the printed circuit board 16 at locations without internal via connections 22, and positions of ground solder balls 32 that may not be soldered to the printed circuit board 16 at locations with internal via connections 22.

In the illustrated example, each radio frequency solder ball RF may be surrounded by three ground solder balls at each side. Here, the ground solder balls 32 directly arranged between adjacent radio frequency solder balls RF may be arranged over an internal via connection 22 of the printed circuit board 16. These ground solder balls 32 may not be soldered to the printed circuit board 16. Usage of such non-soldered ground solder balls 32 may result in an improved isolation between radio frequency channels, in particular for cases where no via-in-lands are used in the printed circuit board 16.

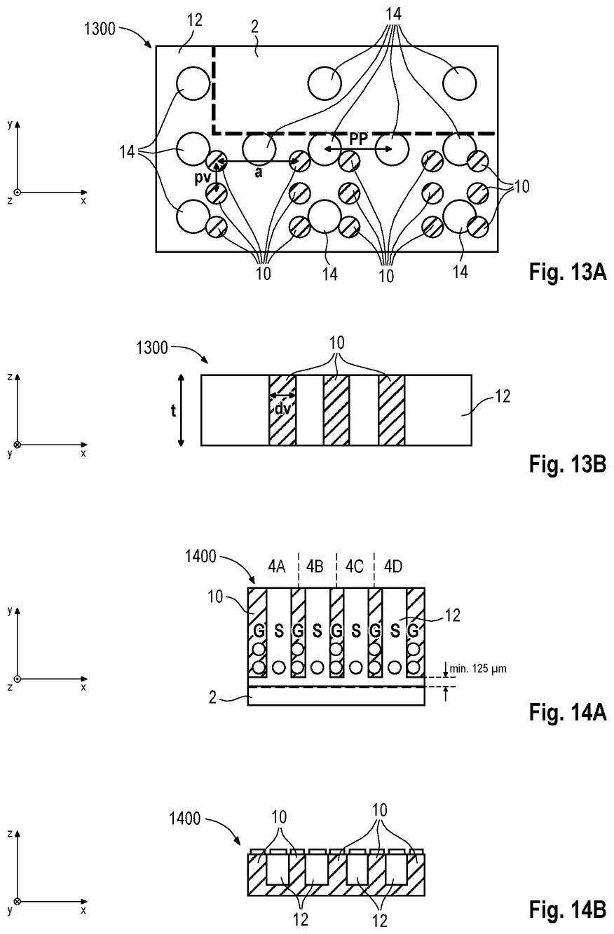

FIGS. 13A and 13B schematically illustrate a top view and a cross-sectional side view of a semiconductor package 1300 in accordance with the disclosure. The semiconductor package 1300 may include some or all features of previously discussed semiconductor packages in accordance with the disclosure. FIGS. 13A and 13B show various example dimensions that may occur in semiconductor packages in accordance with the disclosure.

A distance “pv” in the y-direction between neighboring components of the shielding structure 10 may be referred to as via pitch and may be in a range from about 50 μm to about 500 μm. A dimension “dv” in the x-direction of a component of the shielding structure 10 may be referred to as via diameter and may be in a range from about 20 μm to about 250 μm. A distance “a” in the x-direction between neighboring components of the shielding structure 10 may be in a range from about 100 μm to about 1000 μm. A thickness “t” in the z-direction of the housing formed by the encapsulation material 12 may be in a range from about 100 μm to about 800 μm.

A typical or preferred value of “pv” may be about 250 μm in one example. A typical or preferred value of “dv” may be about 120 μm in one example. A typical or preferred value of “a” may be about 700 μm in one example. A typical or preferred value of “t” may be about 450 μm in one example.

Generic dimensions based on a wavelength λ associated with operating frequencies of the semiconductor package 1300 may be as follows. The distance “pv” may be smaller than about 1/4 of λ. The dimension “dv” may be smaller than about 1/8 of λ. The distance “a” may be smaller than about 1/2 of λ. The thickness “t” may be smaller than about 1/2 of λ.

Generic dimensions based on an example wavelength λ of about 77 GHz and an example value of about 3.7 for a dielectric constant of the encapsulation material 12 may be as follows. The distance “pv” may have a value of about 0.12 of λ_{77GHZ}. The dimension “dv” may have a value of about 0.06 of λ_{77GHZ}. The distance “a” may have a value of about 0.35 of λ_{77GHZ}. The thickness “t” may have a value of about 0.25 of λ_{77GHz}.

A distance “PP” between neighboring external connection elements 14 may be referred to as package pitch. Generic dimensions based on the package pitch PP may be as follows. The distance “pv” may be smaller than about 1/2 of PP. The dimension “dv” may be smaller than about 1/2 of PP. The distance “a” may be larger than about 1/2 of PP. The thickness “t” may be smaller than PP.

FIGS. 14A and 14B schematically illustrate a top view and a cross-sectional side view of a semiconductor package 1400 in accordance with the disclosure. The semiconductor package 1400 may include some or all features of previously discussed semiconductor packages in accordance with the disclosure. A shielding structure 10 of the semiconductor package 1400 may include a semiconductor material, such as e.g., silicon. In particular, the semiconductor material may include multiple trenches (or openings) filled with an encapsulation material 12, such as e.g., a mold compound. In the illustrated example, the shielding structure 10 may form a comb-like structure. For example, the semiconductor material forming the shielding structure 10 may be similar to the semiconductor material forming the semiconductor chip 2.

The semiconductor material of the shielding structure 10 may have absorbing or conducting properties. In particular, the semiconductor material of the shielding structure 10 may be doped to such an extent that the shielding structure 10 may be configured to absorb radiation having a frequency in one of the operating frequency ranges of the semiconductor package 1400. Accordingly, the semiconductor material may increase isolation between neighboring signal ports 4A to 4D of the semiconductor package 1400. An example distance between an edge of the semiconductor chip 2 and the signal ports 4 may be in a range from about 100 μm to about 150 μm, for example about 125 μm.

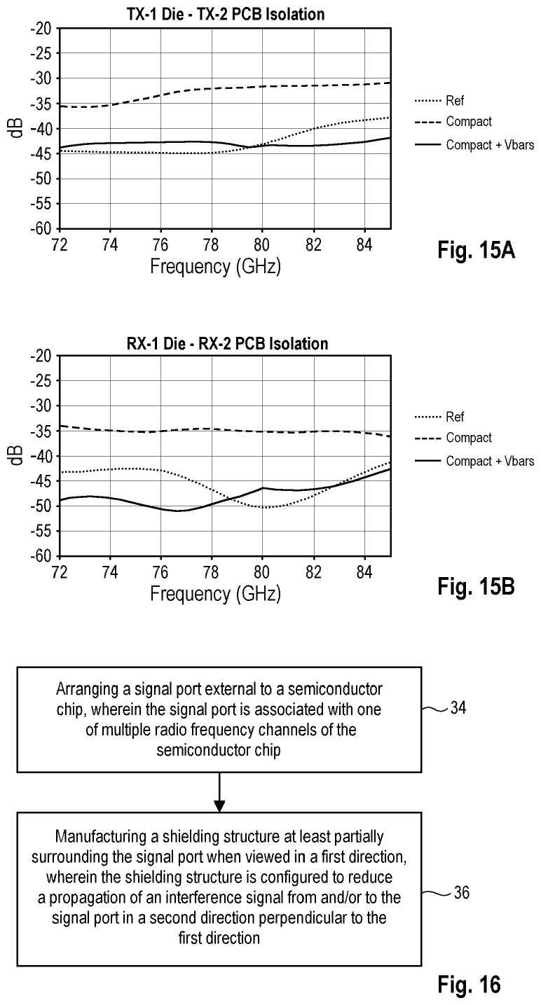

FIG. 15 includes FIGS. 15A and 15B illustrating isolation properties of various semiconductor packages as a function of an operating frequency (in GHz). FIG. 15A relates to isolation properties between a first transmission channel TX-1 associated with a semiconductor die of the respective semiconductor package and a second transmission channel TX-2 associated with a printed circuit board on which the respective semiconductor package may be mounted. In a similar fashion, FIG. 15B relates to isolation properties between a first reception channel RX-1 associated with a semiconductor die of the respective semiconductor package and a second reception channel RX-2 associated with a printed circuit board on which the respective semiconductor package may be mounted.

Dotted curves relate to a reference semiconductor package including two rows of ground solder balls between neighboring signal line portions, such as e.g., the semiconductor package 1000A of FIG. 10. Solid curves relate to a compact semiconductor package including only one row of ground solder balls between neighboring signal line portions (such as c.g., the semiconductor package 1000B of FIG. 10) and including a shielding structure in accordance with the disclosure. Dashed curves relate to a similar compact semiconductor package, but not including a shielding structure in accordance with the disclosure. A comparison between the illustrated curves shows that an isolation level similar to a reference package may be obtained for a compact package including a shielding structure in accordance with the disclosure.

FIG. 16 illustrates a flowchart of a method for manufacturing a semiconductor package in accordance with the disclosure. The method may be used for manufacturing devices as previously described and may thus be read in connection with any of the foregoing figures. The method of FIG. 16 is described in a general manner in order to qualitatively specify aspects of the disclosure. It is understood that the method may include further aspects. For example, the method may be extended by any of the aspects described in connection with other examples in accordance with the disclosure.

At 34, a signal port may be arranged external to a semiconductor chip, wherein the signal port may be associated with one of multiple radio frequency channels of the semiconductor chip. At 36, a shielding structure may be manufactured at least partially surrounding the signal port when viewed in a first direction, wherein the shielding structure may be configured to reduce a propagation of an interference signal from and/or to the signal port in a second direction perpendicular to the first direction.

FIG. 17 includes FIGS. 17A to 17J schematically illustrating a method for manufacturing a semiconductor package 1700 in accordance with the disclosure including a shielding structure made of a semiconductor material. For example, the method may also be used for manufacturing the semiconductor package 1400 of FIG. 14.

In FIG. 17A, the top side of a semiconductor wafer (or a semiconductor substrate) 40 may be coated with an etch resist 38. For example, the semiconductor wafer 40 may be made of silicon. The etch resist 38 may have multiple openings at positions where trenches (or openings) are to be formed in the semiconductor wafer 40 later on.

In FIG. 17B, trenches (or openings) 42 may be formed in the semiconductor wafer 40, for example based on an etching technique. The trenches 42 may be formed in the openings of the etch resist 38. In the illustrated example, the trenches 42 may substantially extend in the vertical z-direction.

In FIG. 17C, the etch resist 38 may be removed or stripped. The top surface of the semiconductor wafer 40 may now be structured by the trenches 42 and may include multiple elevations in form of bars. The bars may form components of a shielding structure 10. In the illustrated example, the shielding structure 10 may have a comb-like structure.

In FIG. 17D, the arrangement may be overmolded with an encapsulation material 12, such as e.g., a mold compound. The mold compound 12 may fill the trenches 42 and may extend over the top surface of the semiconductor wafer 40.

In FIG. 17E, the mold compound 12 may be removed at least partially from the top surface of the arrangement, for example based on a grinding technique. After removing the mold compound 12, the top surfaces of the semiconductor wafer 40 and the mold compound 12 may be substantially arranged in a common plane. The semiconductor wafer 40 may now include multiple trenches filled with the mold compound 12.

In FIG. 17F, semiconductor material may optionally be removed from the bottom surface of the semiconductor wafer 40, for example based on a grinding technique.

In FIG. 17G, the semiconductor wafer 40 including the filled trenches may be diced along the dashed lines and may be separated in multiple components. Each of the separated components may be of a substantially rectangular shape and may include semiconductor material with filled trenches. Each separated component may include a shielding structure 10.

In FIG. 17H, multiple semiconductor dies 2 may be arranged on a carrier 46, such as e.g., a metal carrier. For example, the semiconductor dies 2 may be obtained by dicing and singulating a further suitably processed semiconductor wafer (see “Active dies”). In addition, components including shielding structures 10 and obtained by the act of FIG. 17G may be arranged on the carrier 46. The components including the shielding structures 10 may be arranged adjacent to the semiconductor dies 2 as exemplarily shown in FIG. 17H.

In FIG. 17I, the arrangement may be overmolded by an encapsulation material, such as e.g., a mold compound. The encapsulation material including the semiconductor dies 2 and the shielding structures 10 embedded therein may form a reconstituted wafer 44. For example, the reconstituted wafer 44 may be manufactured based on a FOWLP (Fan-Out Wafer Level Processing) technique. FIG. 17I may include further method steps which are not explicitly discussed herein for the sake of simplicity, such as e.g., forming an electrical redistribution layer, applying external connection elements, testing, etc. In yet a further method step, the reconstituted wafer 44 may be diced along the dashed lines and separated in multiple semiconductor packages in accordance with the disclosure.

FIG. 17J illustrates one of multiple semiconductor packages 1700 obtained by singulating the reconstituted wafer 44 of FIG. 17I. For example, the semiconductor package 1700 may be similar to the semiconductor package 1400 of FIG. 14B.

### ASPECTS

In the following, semiconductor packages in accordance with the disclosure and methods for manufacturing thereof are explained using aspects.

Aspect 1 is a semiconductor package, comprising: a semiconductor chip comprising multiple radio frequency channels; a signal port arranged external to the semiconductor chip and associated with one of the multiple radio frequency channels; and a shielding structure at least partially surrounding the signal port when viewed in a first direction, wherein the shielding structure is configured to reduce a propagation of an interference signal from and/or to the signal port in a second direction perpendicular to the first direction.

Aspect 2 is a semiconductor package according to Aspect 1, further comprising: an encapsulation material at least partially encapsulating the semiconductor chip, wherein the shielding structure is arranged in the encapsulation material and configured to reduce the propagation of the interference signal through the encapsulation material in the second direction.

Aspect 3 is a semiconductor package according to Aspect 1 or 2, further comprising: a ball grid array substrate, wherein the shielding structure is arranged in the ball grid array substrate and configured to reduce the propagation of the interference signal through the ball grid array substrate in the second direction.

Aspect 4 is a semiconductor package according to one of the preceding Aspects, wherein the shielding structure comprises an electrically conductive material.

Aspect 5 is a semiconductor package according to one of the preceding Aspects, wherein the shielding structure is formed by one or multiple three-dimensional metal components.

Aspect 6 is a semiconductor package according to Aspect 5, wherein the one or multiple metal components comprise at least one of a metal via, a metal strip, a metal bar, a metal wall or a metal mesh.

Aspect 7 is a semiconductor package according to one of the preceding Aspects, wherein the shielding structure comprises a semiconductor material.

Aspect 8 is a semiconductor package according to Aspect 7, wherein the semiconductor material comprises multiple trenches filled with a mold compound.

Aspect 9 is a semiconductor package according to one of the preceding Aspects, wherein the shielding structure is configured to provide an electrical shielding between the signal port and an adjacent signal port associated with a further radio frequency channel of the multiple radio frequency channels.

Aspect 10 is a semiconductor package according to one of the preceding Aspects, wherein the signal port comprises a ground line portion at least partially surrounding a signal line portion.

Aspect 11 is a semiconductor package according to Aspect 10, wherein the signal port shares a same ground line portion with an adjacent signal port, the ground line portion being between the signal line portion of the signal port and the signal line portion of the adjacent signal port when viewed in the first direction.

Aspect 12 is a semiconductor package according to one of the preceding Aspects, further comprising: an electrical redistribution layer comprising a signal line, wherein the signal line provides an electrical connection between the signal port and the semiconductor chip, and wherein the shielding structure at least partially surrounds the signal line.

Aspect 13 is a semiconductor package according to Aspect 12, wherein: the shielding structure exclusively surrounds the signal port, or the shielding structure exclusively surrounds the signal port and the signal line.

Aspect 14 is a semiconductor package according to one of the preceding Aspects, wherein the shielding structure is electrically connected to a non-floating electrical potential.

Aspect 15 is a semiconductor package according to one of Aspects 12 to 14, wherein the shielding structure is electrically connected to a ground metallization of the electrical redistribution layer.

Aspect 16 is a semiconductor package according to one of the preceding Aspects, further comprising: an external connection element configured to mechanically and electrically connect the semiconductor package to a printed circuit board, wherein the external connection element at least partially overlaps the shielding structure when viewed in the first direction.

Aspect 17 is a semiconductor package according to Aspect 16, wherein the external connection element overlapping the shielding structure is a ground solder ball.

Aspect 18 is a semiconductor package according to Aspect 17, wherein: the ground solder ball is arranged over an internal via connection of a printed circuit board, and the ground solder ball is not soldered to the printed circuit board.

Aspect 19 is a semiconductor package according to one of Aspects 5 to 18, further comprising: a metal layer arranged over the shielding structure and extending in the second direction, wherein the metal layer electrically connects multiple metal components of the shielding structure.

Aspect 20 is a semiconductor package according to Aspect 19 and Aspect 2, wherein the metal layer covers at least 80% of the top surface of the encapsulation material.

Aspect 21 is a semiconductor package according to one of the preceding Aspects, further comprising: an absorber material arranged over the shielding structure, wherein the absorber material is configured to absorb interference signals generated by at least one of the multiple radio frequency channels.

Aspect 22 is a semiconductor package according to Aspect 21 and Aspect 2, wherein the absorber material covers at least 80% of the top surface of the encapsulation material.

Aspect 23 is a semiconductor package according to one of the preceding Aspects, wherein the signal port and the shielding structure are laterally displaced to the semiconductor chip when viewed in the first direction.

Aspect 24 is a semiconductor package according to one of Aspects 2 to 23, further comprising: one or multiple electrically conductive elements arranged in the encapsulation material and over a top surface of the semiconductor chip, wherein the electrically conductive elements are configured to reduce a propagation of interference signals through the encapsulation material in the second direction.

Aspect 25 is a method for manufacturing a semiconductor package, wherein the method comprises: arranging a signal port external to a semiconductor chip, wherein the signal port is associated with one of multiple radio frequency channels of the semiconductor chip; and manufacturing a shielding structure at least partially surrounding the signal port when viewed in a first direction, wherein the shielding structure is configured to reduce a propagation of an interference signal from and/or to the signal port in a second direction perpendicular to the first direction.

As employed in this specification, the terms “connected”, “coupled”, “electrically connected”, and/or “electrically coupled” may not necessarily mean that elements must be directly connected or coupled together. Intervening elements may be provided between the “connected”, “coupled”, “electrically connected”, or “electrically coupled” elements.

Further, the word “over” used with regard to e.g., a material layer formed or located “over” a surface of an object may be used herein to mean that the material layer may be located (e.g., formed, deposited, etc.) “directly on”, e.g., in direct contact with, the implied surface. The word “over” used with regard to e.g., a material layer formed or located “over” a surface may also be used herein to mean that the material layer may be located (e.g., formed, deposited, etc.) “indirectly on” the implied surface with e.g., one or multiple additional layers being arranged between the implied surface and the material layer.

Furthermore, to the extent that the terms “having”, “containing”, “including”, “with”, or variants thereof are used in either the detailed description or the claims, such terms are intended to be inclusive in a manner similar to the term “comprising”. That is, as used herein, the terms “having”, “containing”, “including”, “with”, “comprising”, and the like are open-ended terms that indicate the presence of stated elements or features, but do not preclude additional elements or features. The articles “a”, “an”, and “the” are intended to include the plural as well as the singular, unless the context clearly indicates otherwise.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or multiple” unless specified otherwise or clear from context to be directed to a singular form. Also, at least one of A and B or the like generally means A or B or both A and B.

Devices and methods for manufacturing devices are described herein. Comments made in connection with a described device may also hold true for a corresponding method and vice versa. For example, if a specific component of a device is described, a corresponding method for manufacturing the device may include an act of providing the component in a suitable manner, even if such act is not explicitly described or illustrated in the figures.

Although the disclosure has been shown and described with respect to one or multiple implementations, equivalent alterations and modifications will occur to others skilled in the art based at least in part upon a reading and understanding of this specification and the annexed drawings. The disclosure includes all such modifications and alterations and is limited only by the concept of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated example implementations of the disclosure. In addition, while a particular feature of the disclosure may have been disclosed with respect to only one of several implementations, such feature may be combined with one or multiple other features of the other implementations as may be desired and advantageous for any given or particular application.

1. A semiconductor package, comprising:
a semiconductor chip comprising multiple radio frequency channels;
a signal port arranged external to the semiconductor chip and associated with one of the multiple radio frequency channels; and
a shielding structure at least partially surrounding the signal port when viewed in a first direction, wherein the shielding structure is configured to reduce a propagation of an interference signal at least from or to the signal port in a second direction perpendicular to the first direction.

2. The semiconductor package of claim 1, further comprising:
an encapsulation material at least partially encapsulating the semiconductor chip, wherein the shielding structure is arranged in the encapsulation material and configured to reduce the propagation of the interference signal through the encapsulation material in the second direction.

3. The semiconductor package of claim 1, further comprising:
a ball grid array substrate, wherein the shielding structure is arranged in the ball grid array substrate and configured to reduce the propagation of the interference signal through the ball grid array substrate in the second direction.

4. The semiconductor package of claim 1, wherein the shielding structure comprises an electrically conductive material.

5. The semiconductor package of claim 1, wherein the shielding structure is formed by one or multiple three-dimensional metal components.

6. The semiconductor package of claim 5, wherein the one or multiple three-dimensional metal components comprise at least one of a metal via, a metal strip, a metal bar, a metal wall, or a metal mesh.

7. The semiconductor package of claim 1, wherein the shielding structure comprises a semiconductor material.

8. The semiconductor package of claim 7, wherein the semiconductor material comprises multiple trenches filled with a mold compound.

9. The semiconductor package of claim 1, wherein the shielding structure is configured to provide an electrical shielding between the signal port and an adjacent signal port associated with a further radio frequency channel of the multiple radio frequency channels.

10. The semiconductor package of claim 1, wherein the signal port comprises a ground line portion at least partially surrounding a signal line portion.

11. The semiconductor package of claim 10, wherein the signal port shares a same ground line portion with an adjacent signal port, the ground line portion being between the signal line portion of the signal port and a signal line portion of the adjacent signal port when viewed in the first direction.

12. The semiconductor package of claim 1, further comprising:
an electrical redistribution layer comprising a signal line, wherein the signal line provides an electrical connection between the signal port and the semiconductor chip, and wherein the shielding structure at least partially surrounds the signal line.

13. The semiconductor package of claim 12, wherein:
the shielding structure exclusively surrounds the signal port, or
the shielding structure exclusively surrounds the signal port and the signal line.

14. The semiconductor package of claim 1, wherein the shielding structure is electrically connected to a non-floating electrical potential.

15. The semiconductor package of claim 12, wherein the shielding structure is electrically connected to a ground metallization of the electrical redistribution layer.

16. The semiconductor package of claim 1, further comprising:
an external connection element configured to mechanically and electrically connect the semiconductor package to a printed circuit board, wherein the external connection element at least partially overlaps the shielding structure when viewed in the first direction.

17. The semiconductor package of claim 16, wherein the external connection element overlapping the shielding structure is a ground solder ball.

18. The semiconductor package of claim 17, wherein:
the ground solder ball is arranged over an internal via connection of a printed circuit board, and
the ground solder ball is not soldered to the printed circuit board.

19. The semiconductor package of claim 5, further comprising:
a metal layer arranged over the shielding structure and extending in the second direction, wherein the metal layer electrically connects multiple metal components of the shielding structure.

20. The semiconductor package of claim 19, wherein the metal layer covers at least 80% of a top surface of the encapsulation material.

21. The semiconductor package of claim 1, further comprising:
an absorber material arranged over the shielding structure, wherein the absorber material is configured to absorb interference signals generated by at least one of the multiple radio frequency channels.

22. The semiconductor package of claim 21, wherein the absorber material covers at least 80% of a top surface of the encapsulation material.

23. The semiconductor package of claim 1, wherein the signal port and the shielding structure are laterally displaced to the semiconductor chip when viewed in the first direction.

24. The semiconductor package of claim 2, further comprising:
one or multiple electrically conductive elements arranged in the encapsulation material and over a top surface of the semiconductor chip, wherein the one or multiple electrically conductive elements are configured to reduce a propagation of interference signals through the encapsulation material in the second direction.

25. A method for manufacturing a semiconductor package, wherein the method comprises:
arranging a signal port external to a semiconductor chip, wherein the signal port is associated with one of multiple radio frequency channels of the semiconductor chip; and
manufacturing a shielding structure at least partially surrounding the signal port when viewed in a first direction, wherein the shielding structure is configured to reduce a propagation of an interference signal at least from or to the signal port in a second direction perpendicular to the first direction.
